(19) United States
(12) Patent Application Publication
(10) Pub. No.: US 2025/0112438 A1
(43) Pub. Date: Apr. 3, 2025

(54) LIGHT-EMITTING MODULE AND METHOD FOR MANUFACTURING LIGHT-EMITTING MODULE

(71) Applicants: NICHIA CORPORATION, Anan-shi, Tokushima (JP); FURUKAWA ELECTRIC CO., LTD., Tokyo (JP)

(72) Inventors: Kazuya HATAKEYAMA, Yokohama-shi (JP); Atsushi HIGASHIURA, Ichikawa-shi (JP)

(73) Assignees: NICHIA CORPORATION, Anan-shi, Tokushima (JP); FURUKAWA ELECTRIC CO., LTD., Tokyo (JP)

(21) Appl. No.: 18/893,667

(22) Filed: Sep. 23, 2024

(30) Foreign Application Priority Data
Sep. 28, 2023 (JP) 2023-167749

(51) Int. Cl. H01S 5/02375; H01S 5/00; H01S 5/02257; H01S 5/02315; H01S 5/0236

(52) U.S. Cl. CPC H01S 5/02375; H01S 5/0071; H01S 5/02257; H01S 5/02315; H01S 5/0236

(57) ABSTRACT

A light-emitting module includes: a light-emitting device; and a base that is electroconductive, the base including: a mounting surface that faces a first direction and on which the light-emitting device is mounted with a bonding material, and at least one protrusion that is adjacent to the mounting surface in a direction intersecting the first direction and protrudes in the first direction with respect to the mounting surface. The at least one protrusion includes a plurality of first surfaces that are in contact with the light-emitting device. The light-emitting device includes a light-emitting element and has a side surface at which an electroconductive part electrically connected to an electrode of the light-emitting element is exposed. The side surface is partially in contact with the first surfaces, and a part of the side surface at which the electroconductive part is exposed is not in contact with the first surfaces.

### CROSS-REFERENCE TO RELATED APPLICATION

This application claims priority from Japanese Patent Application No. 2023-167749 filed on Sep. 28, 2023, the entire contents of which are incorporated herein by reference.

### BACKGROUND OF THE INVENTION

### 1. Field of the Invention

The present disclosure relates to a light-emitting module and a method for manufacturing the light-emitting module.

### 2. Description of the Related Art

Light-emitting modules are known that guide light output from a light-emitting device provided on a base to an end of an optical fiber through a plurality of optical components provided on the base (e.g., PCT Publication No. WO 2017/134911).

### SUMMARY

In this type of light-emitting module, the positioning accuracy of the light-emitting device with respect to the base is important from the viewpoint of increasing the utilization efficiency of light output from the light-emitting device.

In view of this, it is desirable to obtain an improved and novel light-emitting module and a method for manufacturing the light-emitting module, which more reliably or more easily enable the desired positioning accuracy of a light-emitting device with respect to a base.

In some embodiments, a light-emitting module includes: a light-emitting device; and a base that is electroconductive, the base having a mounting surface that faces a first direction and on which the light-emitting device is mounted with a bonding material and at least one protrusion that is adjacent to the mounting surface in a direction intersecting the first direction and relatively protrudes in the first direction with respect to the mounting surface. The at least one protrusion has a plurality of first surfaces that are in contact with the light-emitting device in different directions intersecting the first direction, the light-emitting device includes a light-emitting element and has a side surface on which an electroconductive part electrically connected to an electrode of the light-emitting element is exposed, and the side surface is partially in contact with the first surfaces, and a part at which the electroconductive part is exposed in the side surface is not in contact with the first surfaces.

In some embodiments, provided is a method for manufacturing a light-emitting module, the light-emitting module including: a light-emitting device; and a base having a mounting surface that faces a first direction and on which the light-emitting device is mounted with a bonding material and at least one protrusion that is adjacent to the mounting surface in a direction intersecting the first direction and relatively protrudes in the first direction with respect to the mounting surface, the at least one protrusion having a plurality of first surfaces that are in contact with the light-emitting device in different directions intersecting the first direction. The method includes: as a first step, either applying a bonding material in paste form or placing a bonding material in sheet form on the mounting surface; as a second step after the first step, placing the light-emitting device on the bonding material and the mounting surface with the plurality of first surfaces being in contact with the light-emitting device; as a third step after the second step, heating and melting the bonding material; and as a fourth step after the third step, solidifying the bonding material thereby mounting the light-emitting device on the mounting surface with the bonding material.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary and schematic plan view of a light-emitting module according to an embodiment;

FIG. 2 is an exemplary and schematic perspective view of a portion of the light-emitting module according to the embodiment;

FIG. 3 is an exemplary and schematic plan view of a portion of the light-emitting module according to the embodiment, without the light-emitting module mounted on a base;

FIG. 4 is an exemplary and schematic plan view of the portion of the light-emitting module according to the embodiment, with the light-emitting module mounted on the base;

FIG. 5 is an exemplary and schematic cross-sectional view of a light-emitting device according to the embodiment;

FIG. 6 is a flowchart illustrating an example of a procedure of a method for manufacturing the light-emitting module according to the embodiment;

FIG. 7 is a cross-sectional view taken along VII-VII in FIG. 4;

FIG. 8 is a cross-sectional view taken along VIII-VIII in FIG. 4; and

FIG. 9 is a cross-sectional view taken along IX-IX in FIG. 4.

### DETAILED DESCRIPTION

Exemplary embodiments of the disclosure will now be disclosed. Configurations in the embodiments described below and also the actions and results (effects) brought about by these configurations are examples. The invention can also be made by configurations other than those disclosed in the following embodiments. In addition, according to the disclosure, it is possible to obtain at least one of the various effects (including derivative effects) obtained by the configurations.

In this specification, ordinal numbers are used for convenience in order to distinguish parts, members, areas, directions, and steps, for example, and do not indicate priority or order.

In each drawing, the X-direction is represented by the arrow X, the Y-direction is represented by the arrow Y, and the Z-direction is represented by the arrow Z. The X, Y, and Z-directions intersect each other and are orthogonal to each other. In this specification, a view when seen in the direction opposite to the Z-direction is referred to as a plan view. The directions are directions in a state in which the respective components are incorporated into a light-emitting module.

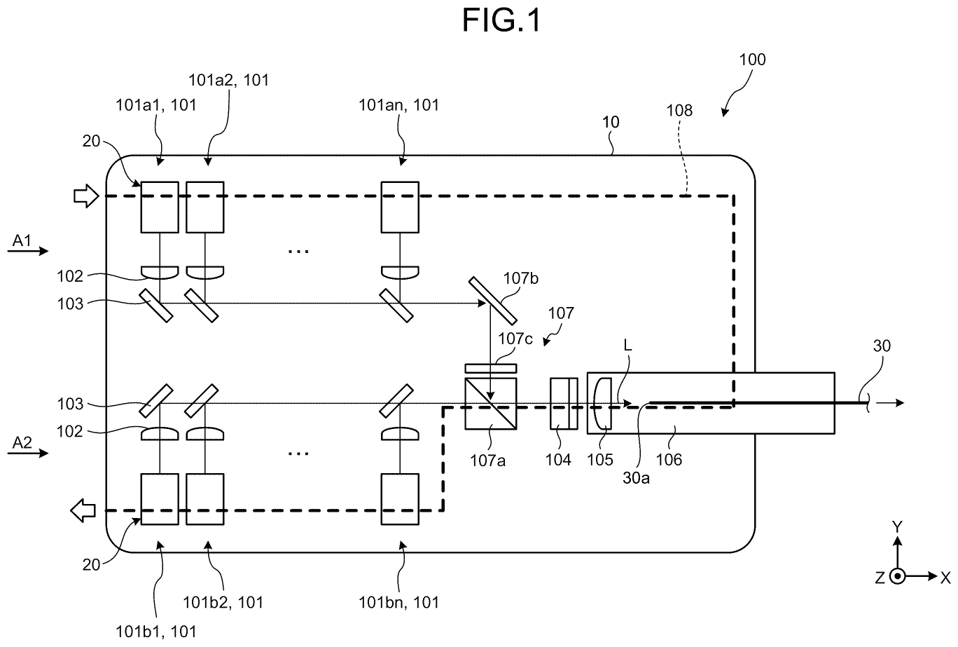

In FIGS. 1 and 5, optical paths of laser beams L are indicated by solid arrows.

### Embodiments

### Configuration of Light-Emitting Module

FIG. 1 is a schematic diagram of a light-emitting module 100 according to the embodiment, which is a plan view of the interior of the light-emitting module 100 when seen in the direction opposite to the Z-direction.

As illustrated in FIG. 1, the light-emitting module 100 includes a base 10, a plurality of subunits 101, a light combining unit 107, condensing lenses 104, 105, an optical fiber 30, and an optical fiber holder 106.

Each subunit 101 includes a laser source 20, a collimating lens 102, and a mirror 103. The collimating lens 102 collimates a laser beam in the X-direction, in the slow-axis direction in this example. In the present embodiment, a collimating lens that collimates the laser beam in the Z-direction, in the fast-axis direction in this example, is included in the laser source 20. However, this is only an example, and the collimating lens that collimates the laser beam in the fast-axis direction may be provided outside the laser source 20, between the laser source 20 and the collimating lens 102. In this case, the collimating lens that collimates the laser beam in the fast-axis direction would be included in the subunit 101. The laser source 20 is an example of a light-emitting device.

A laser beam output from each laser source 20 is guided through the collimating lens 102 and the mirror 103 of the corresponding subunit 101, and then through the light combining unit 107 and the condensing lenses 104, 105 to an end 30a of the optical fiber 30, and is optically coupled to the optical fiber 30. The optical fiber 30 is an example of a first optical component. The collimating lens 102, the mirror 103, the light combining unit 107, and the condensing lenses 104, 105 are examples of second optical components that guide the laser beam output from each of the laser sources 20 to the optical fiber 30 so as to optically connect it to the optical fiber 30.

The subunits 101, the light combining unit 107, the condensing lenses 104, 105, the end 30a of the optical fiber 30, and at least part of the optical fiber holder 106 are all attached directly to the base 10 or indirectly thereto with other members interposed therebetween, and are housed in a housing formed between the base 10 and a cover. As an example, the housing is hermetically sealed; however, the housing need not be hermetically sealed.

The base 10 has a plurality of stepped surfaces, as mounting surfaces for the subunits 101, which face the Z-direction and are each displaced by a fixed length in the direction opposite to the Z-direction as are displaced by a fixed length in the X-direction. The subunits 101 include subunits 101a1, 101a2, . . . , 101an (n is an integer of 2 or, more) that constitute an array A1 aligned in the X-direction and subunits 101b1, 101b2,., 101bn that constitute an array A2 aligned in the X-direction.

Each laser source 20 outputs a laser beam. The laser beam output from the laser source 20 travels in the X-direction through the collimating lens 102 and the mirror 103. As described above, the respective subunits 101 are provided on the stepped mounting surfaces. Thus, the laser beam traveling in the X-direction from the mirror 103 of each subunit 101 does not interfere with the mirrors of other subunits 101 that are displaced in the X-direction with respect to the mirror 103.

The laser beams from the respective mirrors 103 are input to the light combining unit 107 and combined in the light combining unit 107. The light combining unit 107 includes a combiner 107a, a mirror 107b, and a half-wave plate 107c.

The mirror 107b directs the laser beams from the subunits 101 of the array A1 to the combiner 107a through the half-wave plate 107c. The half-wave plate 107c rotates the polarization plane of light from the array A1.

In contrast, the laser beams from the subunits 101 of the array A2 are input directly to the combiner 107a.

The combiner 107a combines the laser beams from the two arrays A1 and A2. The combiner 107a can also be referred to as a polarization combining element.

The laser beam from the combiner 107a is condensed by the condensing lenses 104, 105 toward the end 30a of the optical fiber 30. The condensing lens 104 condenses the laser beam in the fast axis, and the condensing lens 105 condenses the laser beam in the slow axis.

The optical fiber holder 106 holds the optical fiber 30 with, for example, an adhesive interposed therebetween.

The base 10 is made of a material having relatively high thermal conductivity, such as a metallic material. The base 10 is, for example, a copper-based material with a plated surface. The components of the subunits 101, the components of the light combining unit 107, and the condensing lenses 104, 105 are attached to the base 10 with bonding materials such as adhesive or solder. These components may be attached to the base 10 indirectly with other members interposed therebetween. The optical fiber holder 106 may be a member separate from the base 10 or may be part of the base 10.

In the base 10, a refrigerant passage 108 is formed that cools the subunits 101 including the laser sources 20, the optical fiber holder 106, the condensing lenses 104, 105, the combiner 107a, and the like. In the refrigerant passage 108, a refrigerant such as a coolant flows. The refrigerant passage 108 extends, for example, near mounting surfaces of the respective components of the base 10, for example, directly below or near the components. The inner surface of the refrigerant passage 108 and the refrigerant in the refrigerant passage 108 are thermally connected to the components and areas to be cooled, that is, the subunits 101, the optical fiber holder 106, the condensing lenses 104, 105, the combiner 107a, and the like. The components and areas to be cooled are cooled by heat exchange with the refrigerant through the base 10.

### Mounting Structure of Laser Source

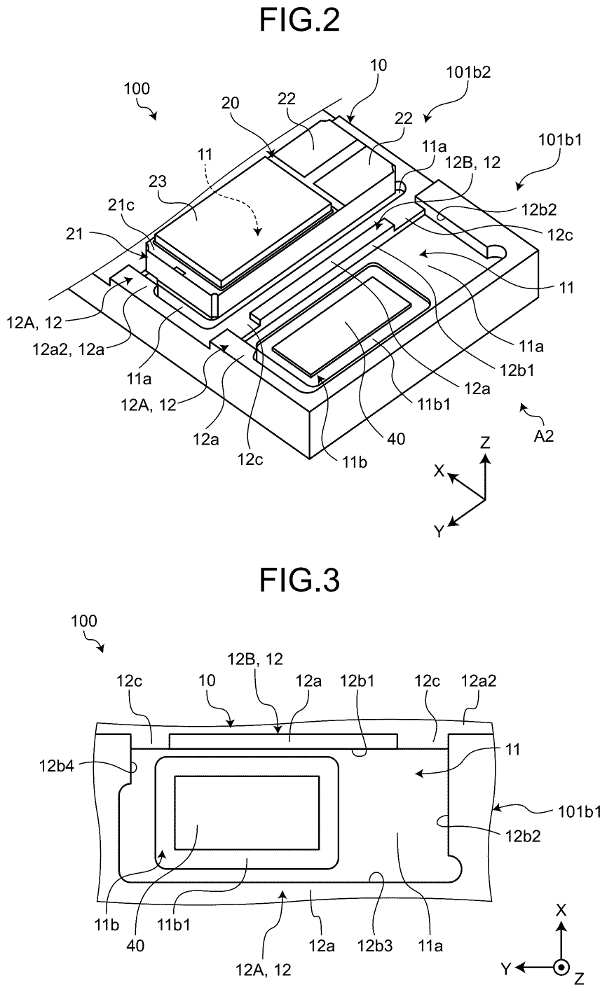

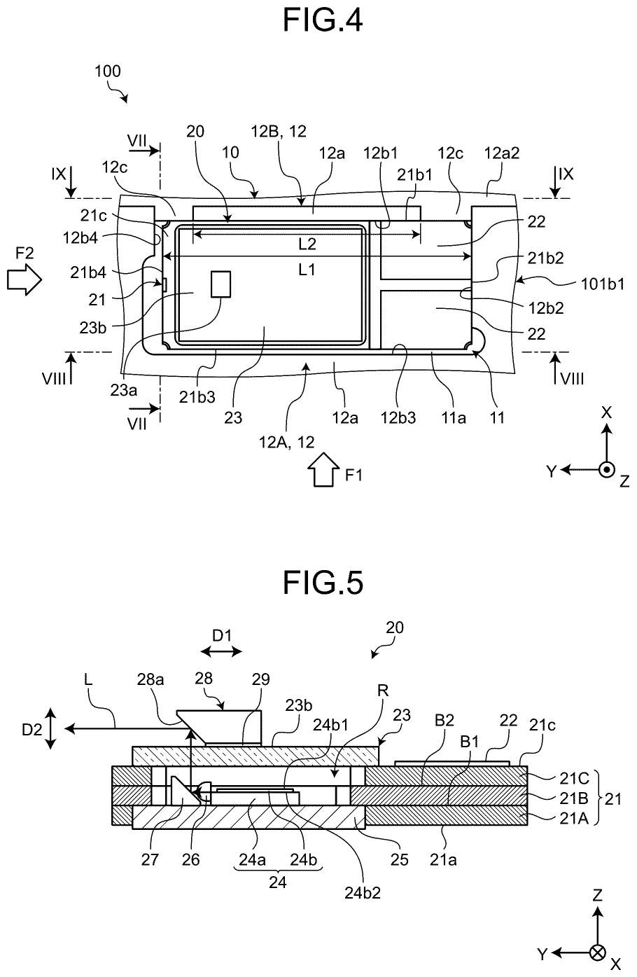

FIG. 2 is a perspective view of a portion of the light-emitting module 100. FIG. 3 is a plan view of a portion of the light-emitting module 100, without the laser source 20 mounted. FIG. 4 is a plan view of the portion of the light-emitting module 100, with the laser source 20 mounted.

FIG. 2 illustrates an area of the base 10 on which the laser sources 20 included in two subunits 101b1, 101b2 of the array A2 are mounted. For convenience of explanation, FIG. 2 illustrates a state in which the laser source 20 of the subunit 101b1 is not yet mounted and the laser source 20 of the subunit 101b2 is mounted.

As illustrated in FIG. 2, on the base 10, a plurality of surfaces 12a are formed. The surfaces 12a each face the Z-direction, and intersect and are orthogonal to the Z-direction. As illustrated in FIG. 2, in the array A2, the surfaces 12a are formed in a stepped manner so as to be each displaced by a fixed length in the direction opposite to the Z-direction as are displaced by a fixed length in the X-direction. Not only the area illustrated in FIG. 2, but all the areas of the base 10 corresponding to two laser sources 20 adjacent to each other in the X-direction in the arrays A1 and A2 have the same shape as in FIG. 2. However, each area of the base 10 corresponding to two laser sources 20 adjacent to each other in the X-direction in the array A1 has a configuration that is a mirror image of that in FIG. 2.

In each surface 12a, a first recess 11 is formed that houses a portion of the corresponding laser source 20. The first recess 11 is recessed in the direction opposite to the Z-direction with respect to the surface 12a at a substantially fixed depth. The first recess 11 has a substantially rectangular shape in a plan view. Thus, the bottom surfaces 11a of the first recesses 11 each have a substantially rectangular shape in a plan view. Each bottom surface 11a faces the Z-direction, and intersects and is substantially orthogonal to the Z-direction. The corresponding laser source 20 is surface mounted on the bottom surface 11a by what is called reflow soldering with a solder 40. The bottom surface 11a is an example of a mounting surface. The solder 40 is an example of a bonding material. The Z-direction is an example of a first direction.

Each bottom surface 11a is displaced by a fixed length (depth) in the direction opposite to the Z-direction with respect to the corresponding surface 12a. As described above, in each of the arrays A1 and A2, the surfaces 12a are formed in a stepped manner so as to be each displaced by a fixed length in the direction opposite to the Z-direction as are displaced by a fixed length in the X-direction. Thus, in each of the arrays A1 and A2, the bottom surfaces 11a are formed in a stepped manner so as to be each displaced by a fixed length in the direction opposite to the Z-direction as are displaced by a fixed length in the X-direction.

With respect to each of these bottom surfaces 11a, the corresponding surface 12a is displaced in the Z-direction. In other words, in the present embodiment, it can be said that, for each of the stepped bottom surfaces 11a, a protrusion 12 having the surface 12a as the top surface is formed. The protrusion 12 relatively protrudes in the Z-direction with respect to the bottom surface 11a at a position adjacent to the bottom surface 11a in a direction intersecting the Z-direction. In the present embodiment, in the base 10, two protrusions 12A and 12B are formed for each bottom surface 11a. However, the number of the protrusions 12 for the bottom surface 11a is not limited to two, and may be one, or may be even 3 or more. In other words, in the base 10, at least one protrusion 12 corresponding to each bottom surface 11a needs to be formed. In the present embodiment, the positions, in the Z-direction, of the top surfaces of a plurality of the protrusions 12 (surfaces 12a in the present embodiment) corresponding to each bottom surface 11a are the same, i.e., flush with each other. In this case, by forming the first recess 11 and notches 12c after forming each surface 12a, the protrusions 12 can be formed with relative ease. The top surfaces of the protrusions 12 may be displaced in the Z-direction. On the surface 12a, the corresponding collimating lens 102 or the corresponding mirror 103 may be mounted at a distance from the first recess 11.

As illustrated in FIGS. 2 and 3, the protrusions 12 have four surfaces 12b1 to 12b4 that form side surfaces of the corresponding first recess 11. The surface 12b1 faces the direction opposite to the X-direction, and intersects and is substantially orthogonal to the X-direction. The surface 12b2 faces the Y-direction, and intersects and is substantially orthogonal to the Y-direction. The surface 12b3 faces the X-direction, and intersects and is substantially orthogonal to the X-direction. The surface 12b4 faces the direction opposite to the Y-direction, and intersects and is substantially orthogonal to the Y-direction.

As illustrated in FIG. 4, the laser source 20 has four side surfaces 21b1 to 21b4 that respectively face the four surfaces 12b1 to 12b4 of the protrusions 12. The side surface 21b1 faces the X-direction, intersects and is substantially orthogonal to the X-direction, and faces the surface 12b1. The side surface 21b2 faces the direction opposite to the Y-direction, intersects and is substantially orthogonal to the Y-direction, and faces the surface 12b2. The side surface 21b3 faces the direction opposite to the X-direction, intersects and is substantially orthogonal to the X-direction, and faces the surface 12b3. The side surface 21b4 faces the Y-direction, intersects and is substantially orthogonal to the Y-direction, and faces the surface 12b4 of the first recess 11.

As illustrated in FIG. 4, the laser source 20 is disposed so as to be shifted in the direction opposite to the Y-direction and in the X-direction in the first recess 11. In other words, the laser source 20 is mounted on the base 10 with the side surface 21b1 being in contact with the surface 12b1 of the protrusion 12B, 12 and the side surface 21b2 being in contact with the surface 12b2 of the protrusion 12A, 12. In other words, in the present embodiment, the surfaces 12b1 and 12b2 are used for positioning the laser source 20 with respect to the base 10. The surfaces 12b1 and 12b2 are in contact with the laser source 20 in different directions intersecting the Z-direction, in the direction opposite to the X-direction and in the Y-direction respectively, as an example in the present embodiment. By this configuration, the laser source 20 can be accurately positioned with respect to the base 10 in different directions intersecting the Z-direction. Furthermore, this configuration can prevent the laser source 20 from being misaligned in a manner rotating around the Z-axis with respect to the base 10. The surfaces 12b1 and 12b2 are examples of the first surfaces and can also be referred to as contact surfaces or positioning surfaces. The direction opposite to the X-direction and the Y-direction are different directions intersecting each other.

As illustrated in FIGS. 2 and 3, in the present embodiment, in each bottom surface 11a, a second recess 11b that accommodates the solder 40 is formed. The second recess 11b is recessed in the direction opposite to the Z-direction with respect to the bottom surface 11a at a substantially fixed depth. The second recess 11b has a substantially rectangular shape in a plan view. Thus, the bottom surfaces 11b1 of the second recesses 11b each have a substantially rectangular shape in a plan view. Each bottom surface 11b1 faces the Z-direction, and intersects and is substantially orthogonal to the Z-direction. The solder 40, before melting, has a rectangular and sheet-like shape that is smaller than the bottom surface 11b1 of the second recess 11b in a plan view and has a substantially fixed thickness. The solder 40 may be in a paste form. The second recess 11b can be used as a positional target for the solder 40 to be placed on the bottom surface 11a before melting. The second recess 11b can accommodate the molten and wet spread solder. In other words, by forming the second recess 11b that accommodates the solder 40 in the bottom surface 11a, an effect of being able to retain the solder 40 in a position suitable for mounting the laser source 20 can be obtained both before and after melting.

### Configuration of Laser Source

FIG. 5 is a cross-sectional view of the laser source 20 as a light-emitting device. As illustrated in FIG. 5, the laser source 20 includes an enclosure 21, electrodes 22, a lid member 23, a chip-on submount 24, a bottom member 25, a collimating lens 26, an internal mirror 27, an external mirror 28, and a bonding material 29.

The enclosure 21 has a laminated structure in which a plurality of plate-shaped members 21A to 21C are stacked. The enclosure 21 is, for example, a ceramic package. In this case, the members 21A to 21C are made of ceramics. The members 21A to 21C are examples of layers. In each of the members 21A to 21C, a through hole is formed. The members 21A to 21C are stacked and integrated such that their through holes overlap in the Z-direction. The lid member 23 is integrated in a manner being in contact with the member 21C in the Z-direction while covering the through hole of the member 21C. The bottom member 25 is integrated in a manner being in contact with the member 21B in the direction opposite to the Z-direction while passing through the through hole of the member 21A and covering the through hole of member 21B. By this configuration, inside the laser source 20, a housing R for components surrounded by the members 21A to 21C, the lid member 23, and the bottom member 25 is formed. The lid member 23 is made of a material such as sapphire or glass that transmits a laser beam. The surface of the lid member 23 at its end in the direction opposite to the Z-direction, except for a window 23a (see FIG. 4) through which the laser beam passes, is covered with a shielding film that shields the laser beam. The shielding film is, for example, a metal film. The bottom member 25 is made of a material having relatively high thermal conductivity such as a metallic material, and functions as a heatsink. The bottom member 25 is integrated into the enclosure 21 in a manner protruding slightly in the direction opposite to the Z-direction from the surface 21a of the enclosure 21 at its end in the direction opposite to the Z-direction.

The electrodes 22 are provided on the surface 21c of the enclosure 21 at its end in the Z-direction, in a position away from the lid member 23. The electrodes 22 are made of a material such as a metallic material having relatively high electrical conductivity. As the metallic material, for example, silver, copper, tungsten, molybdenum, gold, nickel, platinum, titanium, or palladium is used.

The housing R houses the chip-on submount 24, the collimating lens 26, and the internal mirror 27. The chip-on submount 24 includes a submount 24a and a light-emitting element 24b.

The submount 24a has, for example, a plate-like shape that intersects and is substantially orthogonal to the Z-direction. The submount 24a can be made of an insulating material having relatively high thermal conductivity, examples of which include: ceramics such as aluminum nitride, silicon nitride, aluminum oxide, and silicon carbide; and glass. The submount 24a is mounted on the bottom member 25.

The light-emitting element 24b is, for example, a semiconductor laser element having a fast axis and a slow axis. The light-emitting element 24b has a long and narrow shape extending in the Y-direction. The light-emitting element 24b outputs a laser beam L in the Y-direction. The chip-on submount 24 is mounted such that the fast axis of the light-emitting element 24b is along the Z-direction and the slow axis is along the X-direction.

The collimating lens 26 collimates the laser beam L traveling in the Y-direction, in the Z-direction that is the fast-axis direction in this example. The collimating lens 26 is attached to the submount 24a or a lens holder.

The internal mirror 27 reflects the laser beam L passing through the collimating lens 26 and traveling in the Y-direction toward the Z-direction. The laser beam L reflected by the internal mirror 27 passes through the window 23a of the lid member 23 and travels out of the laser source 20.

The external mirror 28 reflects the beam passing through the window 23a and traveling in the Z-direction toward the Y-direction. The external mirror 28 is bonded on the surface 23b of the lid member 23 with the bonding material 29. The surface 23b is located at the end of the lid member 23 in the Z-direction, faces the Z-direction, and intersects and is substantially orthogonal to the Z-direction.

Here, a reflective surface 28a of the external mirror 28 extends in such a direction that it trends toward the Y-direction as it trends toward the Z-direction, i.e., in a direction between the Y-direction and the Z-direction. Thus, by adjusting the relative attaching position of the external mirror 28 with respect to the lid member 23 in the Y-direction as indicated by the arrow D1, the relative position (height) of the laser beam L with respect to the lid member 23 in the Z-direction can be adjusted as indicated by the arrow D2. The direction of the laser beam L can be adjusted by adjusting the respective relative angles of the external mirror 28 around the X, Y, and Z axes relative to the lid member 23. In this case, the external mirror 28 and the lid member 23 are positioned first so that the desired position and direction of the laser beam L can be obtained, by using a jig or other tool before the application of the bonding material 29 or after the application in a flexible state of not yet being solidified. The bonding material 29 is then solidified with the relative positioning being maintained. By this configuration and method, the position and direction of the laser beam L can be adjusted more accurately. The bonding material 29 is, for example, a thermosetting or ultraviolet-curable bonding material. The Z-direction is an example of a second direction, the external mirror 28 is an example of a mirror, and the surface 23b is an example of a second surface.

In the enclosure 21, electroconductive layers made of electroconductive metal material are provided at the boundaries B1 and B2 where the members 21A to 21C are adjacent to each other. The electroconductive layers are electrically connected to an electrode 24b1 or an electrode 24b2 of the light-emitting element 24b via, for example, an electrode or bonding wire provided on the submount 24a. The electroconductive layers are electrically connected to the electrodes 22 via, for example, via holes provided in the enclosure 21. In other words, the electroconductive layers provided at the boundaries B1 and B2 form part of wiring that electrically connects the electrodes 24b1 and 24b2 of the light-emitting element 24b to the electrodes 22 of the laser source 20. As the metallic material of the electroconductive layers, for example, silver, copper, tungsten, molybdenum, gold, nickel, platinum, titanium, palladium, or alloys thereof may be used.

### Mounting of Laser Source on Base

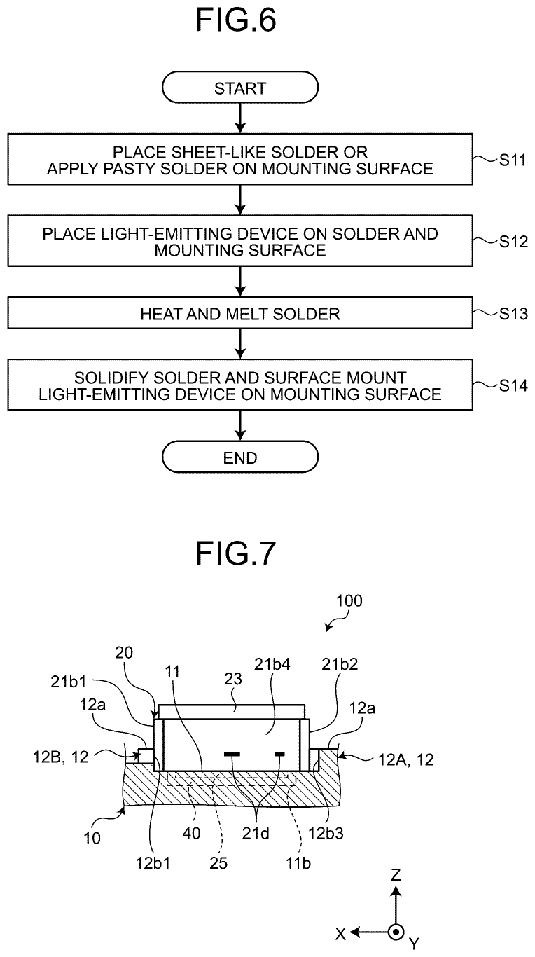

FIG. 6 is a flowchart illustrating an example of a procedure of mounting the laser source 20 on the base 10 in a method for manufacturing the light-emitting module 100. As illustrated in FIG. 6, to begin with, the solder 40 in sheet form is placed or the solder 40 in paste form is applied, on the bottom surface 11a as a mounting surface, onto the bottom surface 11b1 of the second recess 11b in the present embodiment (S11). Subsequently, the laser source 20 as a light-emitting device is placed on the solder 40 and the bottom surface 11a (S12). At S12, in order to reliably bring the solder 40 into contact with the bottom member 25 of the laser source 20, the thickness of the solder 40, the depth of the second recess 11b from the bottom surface 11a, and the protruding height of the bottom member 25 from the surface 21a are preferably set appropriately. S11, S12 are performed sequentially for all bottom surfaces 11a included in the light-emitting module 100. S11 is an example of a first step and S12 is an example of a second step.

Subsequently, the solder 40 is heated to be melted (S13), and the melted solder 40 is cooled and solidified, whereby the laser source 20 is surface mounted on the bottom surface 11a (S14). S13 is an example of a third step and S14 is an example of a fourth step.

When the solder 40 has been melted at S13, the laser source 20 floats on the melted solder 40 and becomes unstable in position and attitude, and may get displaced from a predetermined position when the solder 40 has been solidified at S14. In view of this, in the present embodiment, at S12, the laser source 20 is placed on the solder 40 with the side surface 21b1 being in contact with the surface 12b1 of the protrusion 12B and the side surface 21b2 being in contact with the surface 12b2 of the protrusion 12A. At S13 and S14, this allows the surface 12b1 to be in contact with the side surface 21b1, thereby restricting the movement of the laser source 20 in the X-direction with respect to the base 10, and also allows the surface 12b2 to be in contact with the side surface 21b2, thereby restricting the movement of the laser source 20 in the direction opposite to the Y-direction with respect to the base 10. The friction between the side surface 21b1 and the surface 12b1 may restrict the movement of the laser source 20 in the Y-direction and in the direction opposite to the Y-direction with respect to the base 10, and the friction between the surface 12b2 and the side surface 21b2 may restrict the movement of the laser source 20 in the X-direction and in the direction opposite to the X-direction. Consequently, at S13 and S14, movement of the laser source 20 in a direction intersecting the Z-direction and rotation of the laser source 20 around the Z-axis are suppressed, and the desired positioning accuracy of the laser source 20 with respect to the base 10 can be achieved more reliably or more easily. Even if the bonding material is other than the solder 40, the same effect can be obtained when the bonding material has fluidity until it hardens, or when the volume thereof changes, or when the shape thereof changes, for example. Examples of the bonding material include metal pastes (Au, Ag, Cu, etc.), brazing materials, and resin materials.

At S13 and S14, the laser source 20 may be pressed with a force F1 in the X-direction or may be pressed with a force F2 in the direction opposite to the Y-direction relatively against the base 10 by a pressure member or the like, as illustrated in FIG. 4. The force F1 is a pressing force that presses the side surface 21b1 against the surface 12b1, and the force F2 is a pressing force that presses the side surface 21b2 against the surface 12b2. This makes it possible to more reliably obtain the effects of contact between the surface 12b1 and the side surface 21b1 and contact between the surface 12b2 and the side surface 21b2. The forces F1 and F2 are set as small as possible to the extent that the above-described effects are obtained, and are applied such that the laser source 20 is not tilted. Both of the forces F1 and F2 may be applied, or only one of them may be applied.

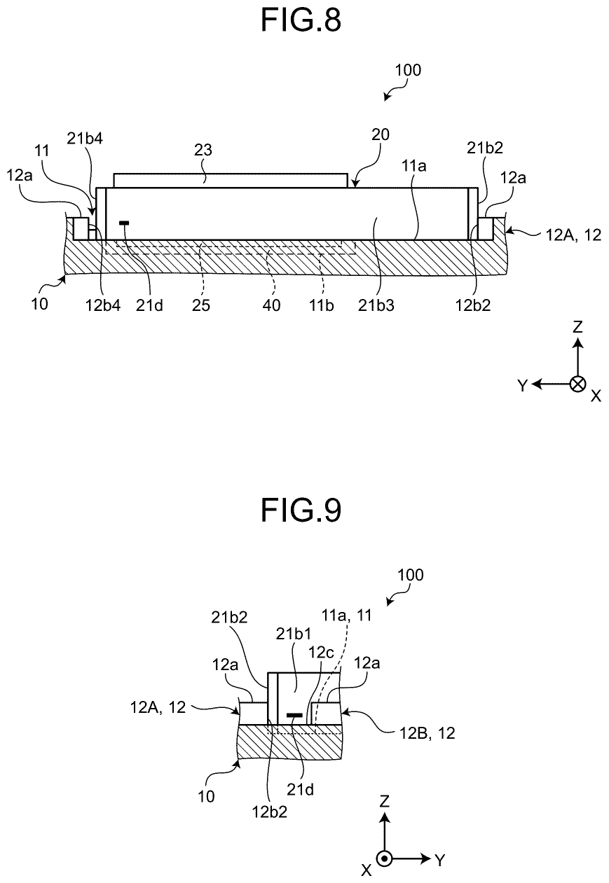

FIGS. 7 to 9 are cross-sectional views illustrating a state after S14, i.e., when surface mounting of the laser source 20 onto the bottom surface 11a has been completed. FIG. 7 is a cross-sectional view taken along VII-VII in FIG. 4. FIG. 8 is a cross-sectional view taken along VIII-VIII in FIG. 4. FIG. 9 is a cross-sectional view taken along IX-IX in FIG. 4.

When the laser source 20 is mounted on the base 10, the side surface 21b1 of the laser source 20 is in contact with the surface 12b1 of the protrusion 12B, as illustrated in FIGS. 7 and 9. As illustrated in FIG. 8, the side surface 21b2 of the laser source 20 is in contact with the surface 12b2 of the protrusion 12A. By the contacts at these two points, the laser source 20 is positioned with respect to the base 10 in the X and Y-directions that are directions intersecting the Z-direction.

In the present embodiment, ends of the electroconductive layer 21d formed on the boundary B1 (see FIG. 5) between the members 21A and 21B are exposed at the side surface 21b4 (FIG. 7), the side surface 21b3 (FIG. 8), and side surface 21b1 (FIG. 9) of the enclosure 21. The electroconductive layer 21d forms part of wiring that electrically connects the electrode 24b1 or the electrode 24b2 of the light-emitting element 24b to the electrodes 22 of the laser source 20. The electroconductive layer 21d is an example of an electroconductive part.

The electroconductive layer 21d is formed by electroplating, for example, on the surface of the member 21A at its end in the Z-direction before the members 21A to 21C are stacked and integrated. The electroplating for the member 21A is performed on an original member in which a plurality of areas for the laser sources 20 (hereinafter, referred to as “package areas”) are arranged in a matrix, and the respective package areas cut out from the original member become the members 21A corresponding to the laser sources 20. In this case, the boundary between the package areas adjacent to each other become a side surface of the member 21A, that is, the enclosure 21. Here, the electroplating is performed on the package areas in the original member by one operation. Thus, the wiring pattern for the electroplating is formed so as to extend over the boundaries of the package areas. Consequently, in the present embodiment, portions of the wiring pattern that extend the boundaries between the package areas are exposed as the ends of the electroconductive layer 21d at the side surfaces 21b1, 21b3, 21b4 of each enclosure 21.

If the base 10 is made of an electroconductive material such as a metallic material, a short circuit may occur between the electrodes 24b1, 24b2 of the light-emitting element 24b and the base 10 when the ends of the electroconductive layer 21d exposed on the side surfaces 21b1, 21b2 have come into contact with the surfaces 12b1, 12b2 of the protrusion 12. In view of this, in the present embodiment, as illustrated in FIG. 9, in the side surface 21b1 that is in contact with the surface 12b1, an end of the electroconductive layer 21d is configured to be exposed at a position away from the protrusion 12B. In other words, in the base 10, the protrusion 12B having the surface 12b1 is formed at a position away from the end of the electroconductive layer 21d. In still other words, a portion of the side surface 21b1 is in contact with the surface 12b1, and a part at which the end of the electroconductive layer 21d is exposed in the side surface 21b1 is not in contact with the surface 12b1. Specifically, as illustrated in FIGS. 2 to 4, in the base 10, the notches 12c that allow the end of the electroconductive layer 21d to be exposed are formed between the protrusions 12A and 12B. By this configuration, when the base 10 is made of an electroconductive material and the end of the electroconductive layer 21d is exposed at the side surface 21b1 of the enclosure 21 of the laser source 20, contact between the electroconductive layer 21d and the base 10 and the resulting short circuit between the base 10 and the electrodes 24b1, 24b2 of the light-emitting element 24b can be prevented. It is also possible to prevent a phenomenon in which the solder 40 in a molten state moves in the Z-direction from the bottom surface 11a through a gap between the side surface 21b1 and the surface 12b1 due to wettability and capillary action, for example, thereby causing a short circuit between the end of electroconductive layer 21d and the surface 12b1 via the solder 40.

As illustrated in FIG. 4, a length L2 in the Y-direction of a part that is in contact with the side surface 21b1 in the surface 12b1 is shorter than a length L1 in the Y-direction of the side surface 21b1 of the laser source 20 that is in contact with the surface 12b1. By this configuration, the notches 12c as portions in which the protrusion 12B and the surface 12b1 are not formed can be formed adjacently to the protrusion 12B having the surface 12b1. If the amount of the solder 40 applied at S12 is larger than the desired amount, when the solder 40 melted at S13 remains in the first recess 11, the solder 40 may solidify while being in contact with the end of the electroconductive layer 21d exposed at the side surface 21b1 at S14 and a short circuit may occur between the end of the electroconductive layer 21d and the surface 12b1 via the solder 40. In this regard, in the present embodiment, even if the amount of the solder 40 is larger than the expected amount, the molten solder 40 can flow out of the first recess 11 from the notches 12c as the non-formed portions at S13. Thus, the occurrence of a short circuit between the end of the electroconductive layer 21d and the surface 12b1 via the solder 40 can be prevented. The Y-direction is an example of a third direction.

As described above, in the present embodiment, the protrusions 12 protruding in the Z-direction (first direction) from the bottom surface 11a (mounting surface) in the base 10 have the surface 12b1 (first surface) that is in contact with the laser source 20 (light-emitting device) in the X-direction and the surface 12b2 (first surface) that is in contact with the laser source 20 in the Y-direction. By this configuration, the laser source 20 is surface mounted on the bottom surface 11a (mounting surface) while being in contact with the surfaces 12b1, 12b2 in different directions, and thus the desired positioning accuracy of the laser source 20 with respect to the base 10 can be more easily or more reliably achieved.

Furthermore, in the present embodiment, the laser source 20 includes the light-emitting element 24b and has the side surface 21b1 on which the electroconductive layer 21d (electroconductive part) electrically connected to the electrodes 24b1, 24b2 of the light-emitting element 24b is exposed. The side surface 21b1 is partially in contact with the surface 12b1 of the protrusion 12B, and a part at which the electroconductive layer 21d is exposed in the side surface 21b1 is not in contact with the surface 12b1. By this configuration, a short circuit between the light-emitting element 24b and the base 10 due to contact between the electroconductive layer 21d and the surface 12b1 can be prevented.

In the present embodiment, in the bottom surface 11a, the second recess 11b that accommodates the solder 40 is formed. By this configuration, the solder 40 can be retained in a position suitable for mounting the laser source 20 both before and after melting, which in turn can prevent the laser source 20 from moving from the desired position as the solder 40 melted at S13 flows. In other words, this configuration more easily or more reliably enables the desired positioning accuracy of the laser source 20 with respect to the base 10.

According to the disclosure, an improved and novel light-emitting module and a method for manufacturing the light-emitting module, which more reliably or more easily enable the desired positioning accuracy of a light-emitting device with respect to a base, can be obtained.

Although specific embodiments have been described in the disclosure for a complete and clear disclosure, the appended claims are not to be thus limited but are to be construed as embodying all modifications and alternative constructions that may occur to one skilled in the art that fairly fall within the basic teaching herein set forth.

What is claimed is:

1. A light-emitting module comprising:
a light-emitting device; and
a base that is electroconductive, the base comprising:
a mounting surface that faces a first direction and on which the light-emitting device is mounted with a bonding material, and
at least one protrusion that is adjacent to the mounting surface in a direction intersecting the first direction and protrudes in the first direction with respect to the mounting surface; wherein:
the at least one protrusion comprises a plurality of first surfaces that are in contact with the light-emitting device and, in a plan view, extend in different directions intersecting the first direction;
the light-emitting device comprises a light-emitting element and has a side surface at which an electroconductive part electrically connected to an electrode of the light-emitting element is exposed; and
the side surface is partially in contact with the first surfaces, and a part of the side surface at which the electroconductive part is exposed is not in contact with the first surfaces.

2. The light-emitting module according to claim 1, wherein a recess configured to accommodate the bonding material is located in the mounting surface.

3. The light-emitting module according to claim 1, wherein:
the light-emitting device comprises an enclosure having the side surface and housing the light-emitting element;
the enclosure comprises a plurality of layers stacked in the first direction; and
the electroconductive part exposed at the side surface is an end of an electroconductive layer that is formed at a boundary between two adjacent layers of the plurality of layers.

4. The light-emitting module according to claim 3, wherein:
the enclosure comprises a window through which light output from the light-emitting element passes in a second direction;
the light-emitting device comprises a mirror configured to reflect light, which has passed through the window and traveled in the second direction, in a direction intersecting the second direction; and
the mirror is bonded on a second surface of the light-emitting device with a bonding material, the second surface facing the second direction.

5. The light-emitting module according to claim 1, wherein a length of each first surface in a third direction intersecting the first direction is shorter than a length of the side surface in the third direction.

6. The light-emitting module according to claim 1, wherein:
the base comprises a plurality of mounting surfaces, the mounting surface being one of the plurality of mounting surfaces; and
the light-emitting module comprises:
a plurality of light-emitting devices, the light-emitting device being one of the plurality of light-emitting devices, and
a plurality of second optical components configured to guide light output from each of the plurality of light-emitting devices to a first optical component.

7. The light-emitting module according to claim 2, wherein:
the base has a plurality of mounting surfaces, the mounting surface being one of the plurality of mounting surfaces; and
the light-emitting module comprises:
a plurality of light-emitting devices, the light-emitting device being one of the plurality of light-emitting devices, and
a plurality of second optical components configured to guide light output from each of the plurality of light-emitting devices to a first optical component.

8. The light-emitting module according to claim 3, wherein
the base has a plurality of mounting surfaces, the mounting surface being one of the plurality of mounting surfaces; and
the light-emitting module comprises:
a plurality of light-emitting devices, the light-emitting device being one of the plurality of light-emitting devices, and
a plurality of second optical components configured to guide light output from each of the plurality of light-emitting devices to a first optical component.

9. The light-emitting module according to claim 4, wherein
the base has a plurality of mounting surfaces, the mounting surface being one of the plurality of mounting surfaces; and
the light-emitting module comprises:
a plurality of light-emitting devices, the light-emitting device being one of the plurality of light-emitting devices, and
a plurality of second optical components configured to guide light output from each of the plurality of light-emitting devices to a first optical component.

10. The light-emitting module according to claim 5, wherein
the base has a plurality of mounting surfaces, the mounting surface being one of the plurality of mounting surfaces; and
the light-emitting module comprises:
a plurality of light-emitting devices, the light-emitting device being one of the plurality of light-emitting devices, and
a plurality of second optical components configured to guide light output from each of the plurality of light-emitting devices to a first optical component.

11. A method for manufacturing a light-emitting module, the method comprising:
providing a light-emitting device;
providing a base comprising:
a mounting surface that faces a first direction, and
at least one protrusion that is adjacent to the mounting surface in a direction intersecting the first direction and protrudes in the first direction with respect to the mounting surface, the at least one protrusion having a plurality of first surfaces;
either applying a bonding material in paste form on the mounting surface, or placing a bonding material in sheet form on the mounting surface;
subsequently, placing the light-emitting device on the bonding material and the mounting surface such that the plurality of first surfaces are in contact with the light-emitting device and, in a plan view, extend in different directions intersecting the first direction;
subsequently, heating and melting the bonding material; and
subsequently, solidifying the bonding material, thereby mounting the light-emitting device on the mounting surface with the bonding material.

12. The method for manufacturing a light-emitting module according to claim 11, wherein:
a recess is formed on the mounting surface; and
in the applying or placing of the bonding material, the bonding material is applied or placed on a bottom surface of the recess.
